(19) United States
(12) Patent Application Publication
(10) Pub. No.: US 2023/0064286 A1
(43) Pub. Date: Mar. 2, 2023

(54) ELECTRONIC APPARATUS AND CONTROL METHOD THEREOF

(71) Applicant: Coretronic Corporation, Hsin-Chu (TW)

(72) Inventors: Wei-Min Chien, Hsin-Chu (TW); Tung-Chou Hu, Hsin-Chu (TW)

(73) Assignee: Coretronic Corporation, Hsin-Chu (TW)

(21) Appl. No.: 17/886,455

(22) Filed: Aug. 12, 2022

(30) Foreign Application Priority Data
Aug. 30, 2021 (CN) 202111001627.5

(51) Int. Cl. H04R 1/02; G10L 15/22; G06F 3/16; H05K 7/20

(52) U.S. Cl. CPC H04R 1/028; G10L 15/22; G06F 3/167; H05K 7/20136

(57) ABSTRACT

An electronic apparatus includes a main body, at least one fan in the main body, an audio receiving module on the main body, and a control module electrically connected to the audio receiving module and the fan. If the audio receiving module receives an activation command, the control module records an instant value of a rotation speed of the fan and controls the rotation speed to be decreased. After the rotation speed is reduced, if the audio receiving module receives a voice command within a predetermined time period, the electronic apparatus executes the voice command, and the control module controls the rotation speed to be returned to the instant value; if the audio receiving module does not receive the voice command within the predetermined time period, the control module controls the rotation speed to be returned to the instant value.

### CROSS-REFERENCE TO RELATED APPLICATION

This application claims the priority benefit of China application serial no. 202111001627.5, filed on Aug. 30, 2021. The entirety of the above-mentioned patent application is hereby incorporated by reference herein and made a part of this specification.

### BACKGROUND OF THE INVENTION

### 1. Field of the Invention

The invention relates to an electronic apparatus and a control method thereof; more particularly, the invention relates to an electronic apparatus including an audio receiving module and a fan and a control method of the electronic apparatus.

### 2. Description of Related Art

Smart speakers are smart home appliances that have become popular in recent years. Users may communicate with the smart speakers through voice commands, and the smart speakers may answer questions raised by the users, provide information in response to the users' demands, or remotely control other electronic appliances. A general smart speaker may only provide information through sound rather than images. Therefore, products that combine displays and the smart speakers have been launched to provide the users with more integrated information through sound and images. However, the size of display screens of the smart speakers is limited, mostly less than 10 inches, and the users are required to be located around the smart speakers within 30 cm to 50 cm to read the displayed information. If the size of the display screens of the smart speakers is increased in consideration of said issue, the volume of the overall apparatus increases, which does not comply with the design trend of miniaturization of electronic products. One solution to said issue is to combine projection apparatuses to the smart speakers. However, heat dissipating requirements of the projection apparatuses are high, and accordingly, noise generated by the high rotation speed of heat dissipating fans may interfere with audio receiving operations of the smart speakers, which may reduce the ability of the smart speakers to receive the voice commands from the users and accordingly pose a negative impact on the users' experience.

The information disclosed in this “BACKGROUND OF THE INVENTION” section is only for enhancement of understanding of the background of the described technology and therefore it may contain information that does not form the prior art that is already known to a person of ordinary skill in the art. Further, the information disclosed in the “BACKGROUND OF THE INVENTION” section does not mean that one or more problems to be resolved by one or more embodiments of the invention was acknowledged by a person of ordinary skill in the art.

### SUMMARY OF THE INVENTION

The invention provides an electronic apparatus and a control method thereof, which can make the electronic apparatus have both good heat dissipating efficiency and audio receiving performance.

Other objectives and advantages of the invention may further be learned from technical features disclosed in the invention.

In order to achieve one or a part or all of the foregoing objectives or other objectives, an embodiment of the invention provides an electronic apparatus that includes a main body, at least one fan, an audio receiving module, and a control module. The fan is disposed in the main body. The audio receiving module is disposed on the main body. The control module is electrically connected to the audio receiving module and the fan. If the audio receiving module receives an activation command, the control module records an instant value of a rotation speed of the fan and controls the rotation speed of the fan to be decreased. After the rotation speed of the fan is reduced, if the audio receiving module receives a voice command within a predetermined time period, the electronic apparatus executes the voice command, and the control module controls the rotation speed of the fan to be returned to the instant value of the rotation speed. By contrast, after the rotation speed of the fan is reduced, if the audio receiving module does not receive the voice command within the predetermined time period, the control module controls the rotation speed of the fan to be returned to the instant value of the rotation speed.

In order to achieve one or a part or all of the foregoing objectives or other objectives, an embodiment of the invention provides a control method of an electronic apparatus. The electronic apparatus includes a main body, at least one fan, an audio receiving module, and a control module. The control method includes following steps. If the audio receiving module receives an activation command, the control module records an instant value of a rotation speed of the fan and controls the rotation speed of the fan to be decreased. After the rotation speed of the fan is reduced, if the audio receiving module receives a voice command within a predetermined time period, the electronic apparatus executes the voice command, and the control module controls the rotation speed of the fan to be returned to the instant value of the rotation speed. By contrast, after the rotation speed of the fan is reduced, if the audio receiving module does not receive the voice command within the predetermined time period, the control module controls the rotation speed of the fan to be returned to the instant value of the rotation speed.

In view of the above, one or more embodiments of the invention have at least one of the following advantages or effects. When the audio receiving module receives the activation command issued by a user, the control module accordingly controls the fan to reduce the rotation speed to prevent overly loud noise of the fan from affecting the audio receiving performance of the audio receiving module on receiving subsequent voice command issued by the user. After the audio receiving module receives the voice command issued by the user, the control module controls the rotation speed of the fan to the instant value to maintain the required heat dissipating capacity. As a result, the electronic apparatus provided in one or more embodiments of the invention may achieve good heat dissipating efficiency and audio receiving performance.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an electronic apparatus according to an embodiment of the invention.

FIG. 2 is a flowchart of a control method of the electronic apparatus depicted in FIG. 1.

FIG. 3 illustrates detailed steps of the control method of the electronic apparatus depicted in FIG. 1.

FIG. 4 illustrates how the audio receiving units depicted in FIG. 4 are arranged.

FIG. 5 illustrates how an audio receiving unit is arranged according to another embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

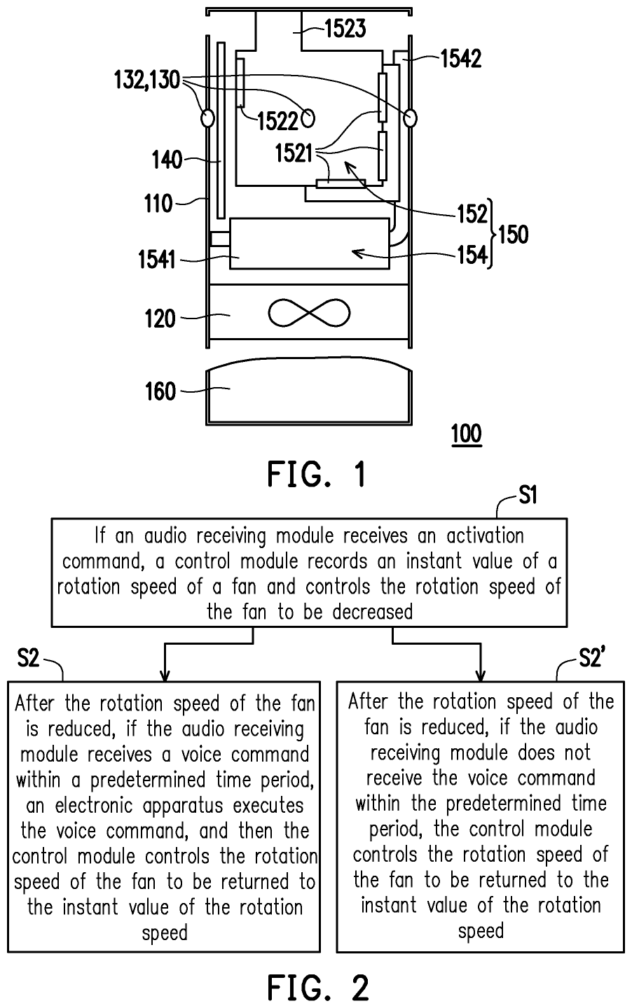

FIG. 1 is a schematic view of an electronic apparatus according to an embodiment of the invention. With reference to FIG. 1, an electronic apparatus 100 provided in this embodiment is, for instance, a smart speaker with an intelligent virtual assistant (IVA) function. The electronic apparatus 100 includes a main body 110, at least one fan 120, an audio receiving module 130, a control module 140, a projection module 150, and a loudspeaker 160. The at least one fan 120, the control module 140, the projection module 150, and the loudspeaker 160 are disposed in the main body 110. The audio receiving module 130 includes, for instance, a plurality of audio receiving units 132 disposed on the main body 110 and configured to receive a voice command issued by a user. The audio receiving module 130 is electrically connected to the control module 140. The control module 140 is, for instance, a control circuit board, which serves to control the loudspeaker 160 to execute the voice command according to the voice command, such as answering questions raised by the user or providing information in response to the user's demands. In addition, the control module 140 is configured to control the projection module 150 to execute the voice command according to the voice command, such as projecting a projection image through the projection module 150 to display the information for the user. In addition, by wirelessly connecting a cloud server, the control module 140 may further remotely control other electronic appliances according to the voice command.

The projection module 150 includes, for instance, a projection unit 152 and a heat dissipating structure 154. A light source 1521 of the projection unit 152 is configured to provide an illumination beam, a light valve 1522 of the projection unit 152 is configured to convert the illumination beam into an image beam, and a projection lens 1523 of the projection unit 152 is configured to project the image beam from the light valve 1522 to form the projection image occupying a large area outside the electronic apparatus 100. The heat dissipating structure 154 includes, for instance, a heat dissipating fin assembly 1541 and a heat pipe 1542. The heat pipe 1542 is connected to the heat dissipating fin assembly 1541, and the heat dissipating fin assembly 1541 is located between the fan 120 and the projection unit 152. The heat pipe 1542 is connected to the light source 1521 of the projection unit 152. The light source 1521 of the projection unit 152 generates a significant amount of heat during operation, and the generated heat is transmitted to the heat dissipating fin assembly 1541 through the heat pipe 1542. The fan 120 is located between the projection unit 152 and the loudspeaker 160, and the fan 120 is configured to provide a heat dissipating airflow to the heat dissipating fin assembly 1541 of the projection module 150 for active heat dissipation.

The at least one fan 120 is electrically connected to the control module 140. The audio receiving module 130 is electrically connected to the control module 140. The projection module 150 is electrically connected to the control module 140. The loudspeaker 160 is electrically connected to the control module 140. The audio receiving unit 132 is, for instance, a microphone. The control module 140 of the electronic apparatus 100 is, for instance, a control chip, and the control chip may execute the function of an intelligent virtual assistant (IVA). The loudspeaker 160 is, for instance, a speaker.

The light source 1521 is, for instance, a light emitting diode (LED) or a laser light source. The light valve 1522 is, for instance, a reflective or transmissive spatial light modulator (SLM). The reflective SLM is, for instance, a reflective liquid crystal on silicon (LCOS) panel, a digital micro-mirror device (DMD), and so forth; the transmissive SLM is, for instance, a transparent liquid crystal panel. The projection lens 1523 includes, for instance, a combination of one or a plurality of optical lenses with refractive power, such as various combinations of non-planar lenses including biconcave lenses, biconvex lenses, concave-convex lenses, convex-concave lenses, plano-convex lenses, and plano-concave lenses.

FIG. 2 is a flowchart of a control method of the electronic apparatus depicted in FIG. 1. With reference to FIG. 2, if the audio receiving module 130 receives an activation command in form of a wake word from the user (e.g., Hey Siri, OK Google, Alexa, etc.), the control module 140 records an instant value of a rotation speed of the fan 120 and controls the rotation speed of the fan 120 to be decreased (step S1). After the rotation speed of the fan 120 is reduced, if the audio receiving module 130 receives a voice command from the user within a predetermined time period, the electronic apparatus 100 executes the voice command, and then the control module 140 controls the rotation speed of the fan 120 to be returned to the instant value of the rotation speed (step S2). By contrast, after the rotation speed of the fan 120 is reduced, if the audio receiving module 130 does not receive the voice command from the user within the predetermined time period, the control module 140 controls the rotation speed of the fan 120 to be returned to the instant value of the rotation speed (step S2′).

As mentioned above, when the audio receiving module 130 receives the activation command issued by the user, the control module 140 accordingly controls the fan 120 to reduce the rotation speed to prevent overly loud noise of the fan 120 from affecting the audio receiving performance of the audio receiving module 130 on receiving the subsequent voice command from the user. The control module 140 controls the fan 120 to reduce the rotation speed, so that the audio receiving module 130 may clearly receive the content of the voice command of the user. After the audio receiving module 130 receives the voice command issued by the user, the control module 140 controls the rotation speed of the fan 120 to be increased (returned) to the instant value recorded previously to maintain the required heat dissipating capacity. As such, the electronic apparatus 100 provided in the embodiment may achieve good heat dissipating efficiency and audio receiving performance.

The number of the fan 120 is not limited in the invention. In other embodiments, the number of the fan 120 may be plural. In addition, when the audio receiving module 130 receives the activation command issued by the user, the control module 140 may merely control the rotation speed of at least one fan 120 or some of the fans 120 located relatively close to the audio receiving module 130 to be reduced and maintain the rotation speed of the other fans 120 relatively far away from the audio receiving module 130. Alternately, when the audio receiving module 130 receives the activation command issued by the user, the control module 140 may control the rotation speed of all the fans 120 to be reduced, which should however not be construed as a limitation to the invention

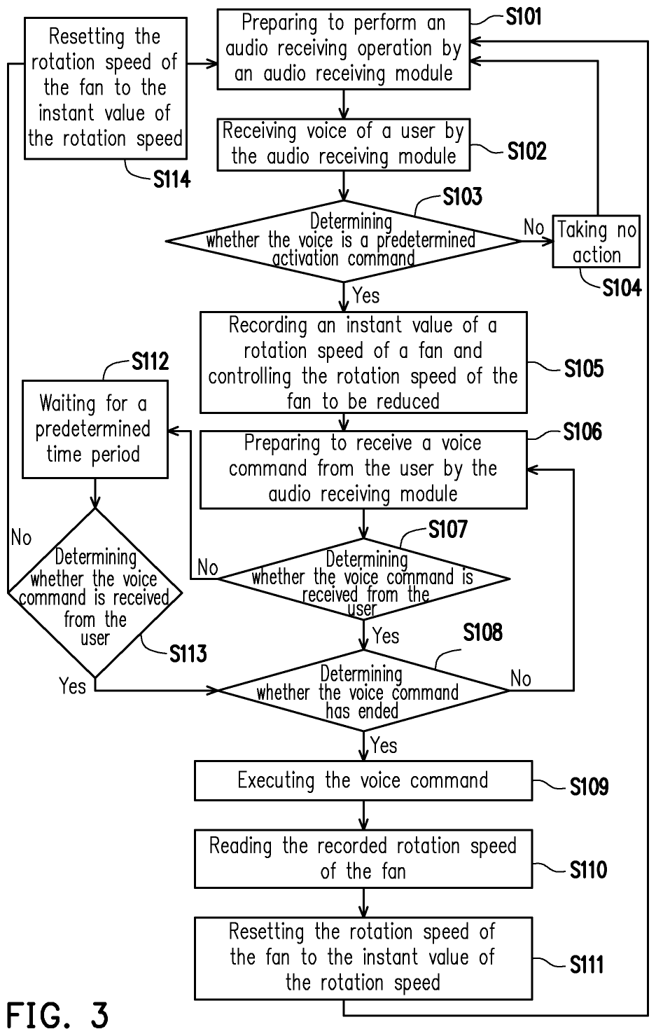

Steps of controlling the electronic apparatus are elaborated hereinafter. FIG. 3 illustrates detailed steps of the control method of the electronic apparatus depicted in FIG. 1. With reference to FIG. 3, first, the audio receiving module 130 prepares to perform an audio receiving operation (step S101). The audio receiving module 130 receives voice of a user (step S102). The control module 140 determines whether the voice is a predetermined activation command (step S103). If the voice is not the predetermined activation command, return to step S101 without taking any action (step S104). If the voice is the predetermined activation command, the control module 140 records an instant value of a rotation speed of the fan 120 and control the rotation speed of the fan 120 to be reduced (step S105). The audio receiving module 130 prepares to receive a voice command from the user (step S106). The control module 140 determines whether the audio receiving module 130 receives the voice command from the user (step S107). If the audio receiving module 130 receives the voice command from the user, the control module 140 determines whether the voice command has ended (step S108). If the voice command has not yet ended, go back to step S106. If the voice command has ended, the electronic apparatus 100 executes the voice command (step S109). Next, the instant value of the rotation speed of the fan 120 recorded in step S105 is read (step S110), the rotation speed of the fan 120 is reset to the instant value of the rotation speed (step S111), and return to step S101.

On the other hand, if the control module 140 determines that the audio receiving module 130 does not receive the voice command from the user in step S107, after waiting for a predetermined time period (step S112), the control module 140 again determines whether the audio receiving module 130 receives the voice command from the user (step S113). If the audio receiving module 130 still does not receive the voice command from the user, the rotation speed of the fan 120 is reset to the instant value of the rotation speed (step S114), and return to step S101. If the audio receiving module 130 receives the voice command from the user, then goes to step S108.

The predetermined time period in step S112 is, for instance, 3 seconds to 5 seconds, which should however not be construed as a limitation to the invention. In addition, in step S105 is, for instance, the rotation speed of the fan 120 is reduced to 30% of the instant value of the rotation speed, so as to reduce the noise of the fan 120 to, for instance, about 23 dB(A), which is roughly the same as the background noise of the indoor environment, which should however not be construed as a limitation to the invention.

Through said steps of the control method, the fan 120 is able to have sufficient air volume to dissipate heat at ordinary times, and when the audio receiving module 130 is required to perform the audio receiving operation, the rotation speed of the fan 120 may be quickly reduced, so that the interference of the noise of the fan 120 to the audio receiving module may be minimized.

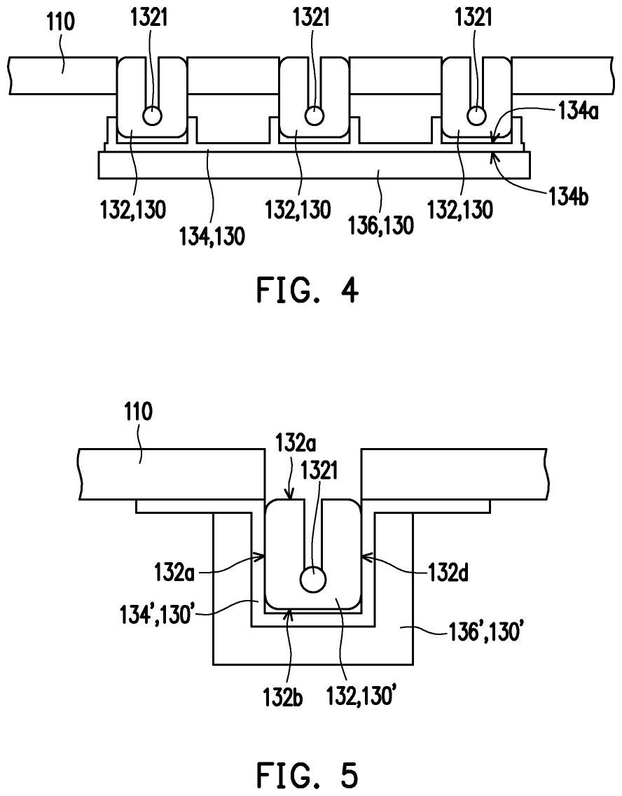

FIG. 1 schematically illustrates that the audio receiving units 132 are circumferentially arranged on a housing of the main body 110 of the device, and the arrangement manner of the audio receiving units 132 is explained hereinafter with reference to the accompanying drawings. FIG. 4 illustrates how the audio receiving units depicted in FIG. 4 are arranged. With reference to FIG. 4, the audio receiving module 130 provided in this embodiment further includes a fixing device 134 and a sound buffer device 136. The fixing device 134 is disposed in the main body 110, the audio receiving units 132 and audio receiving elements 1321 in the audio receiving units 132 are fixed to the fixing device 134, and the sound buffer device 136 is connected to the fixing device 134 to absorb the noise from the fan 120 (shown in FIG. 1). The sound buffer device 136 may be a sound-absorbing device and/or a sound-proof device (such as sound-proof foam), which should not be construed as a limitation to the invention.

In detail, the fixing device 134 has an outer surface 134a and an inner surface 134b opposite to each other. The outer surface 134a faces the outside of the main body 110, and the inner surface 134b faces the inside of the main body 110. The audio receiving units 132 are disposed on the outer surface 134a of the fixing device 134, and the sound buffer device 136 is disposed on the inner surface 134b of the fixing device 134. Thereby, the sound buffer device 136 blocks the audio receiving units 132 from the fan 120 (shown in FIG. 1), so as to effectively suppress the interference of the noise generated by the fan 120 inside the main body 110 to the audio receiving units 132.

FIG. 5 illustrates how an audio receiving unit is arranged according to another embodiment of the invention. The difference between the embodiment shown in FIG. 5 and the embodiment shown in FIG. 4 lies in that a fixing device 134′ of an audio receiving module 130′ depicted in FIG. 5 includes an inverted U-shaped structure that covers the audio receiving unit 132. In addition, a sound buffer device 136′ is disposed along the inverted U-shaped structure and surrounds a plurality of side surfaces 132a, 132b, and 132c of the audio receiving unit 132. As a result, a side surface 132d of the audio receiving unit 132 configured to perform the audio receiving operation does not correspond to the sound buffer device 136′, while the remaining side surfaces 132a, 132b, and 132c all correspond to the sound buffer device 136′. This may effectively prevent the noise generated by the fan 120 inside the main body 110 from interfering with the audio receiving unit 132.

To sum up, one or more embodiments of the invention have at least one of the following advantages or effects. When the audio receiving module receives the activation command issued by the user, the control module accordingly controls the fan to reduce the rotation speed to prevent the overly loud noise of the fan from affecting the audio receiving performance of the audio receiving module on receiving the subsequent voice command issued by the user, so that the audio receiving module is able to clearly determine the content of the voice command of the user. After the audio receiving module receives the voice command issued by the user, the control module controls the rotation speed of the fan to be increased (returned) to the instant value to maintain the required heat dissipating capacity. As a result, the electronic apparatus provided in one or more embodiments of the Invention may achieve good heat dissipating efficiency and audio receiving performance.

The foregoing description of the preferred of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An electronic apparatus, comprising:
a main body;
at least one fan, disposed in the main body;
an audio receiving module, disposed on the main body; and
a control module, electrically connected to the audio receiving module and the at least one fan and configured to:
record an instant value of a rotation speed of the at least one fan and control the rotation speed of the at least one fan to be decreased if the audio receiving module receives an activation command,
after the rotation speed of the at least one fan is reduced, if the audio receiving module receives a voice command within a predetermined time period, the electronic apparatus executes the voice command, and the control module controls the rotation speed of the at least one fan to be returned to the instant value of the rotation speed,
and after the rotation speed of the at least one fan is reduced, if the audio receiving module does not receive the voice command within the predetermined time period, the control module controls the rotation speed of the at least one fan to be returned to the instant value of the rotation speed.

2. The electronic apparatus according to claim 1, wherein the control module is disposed at the main body.

3. The electronic apparatus according to claim 1, further comprising a projection module disposed at the main body, wherein the control module is configured to control the projection module to execute the voice command, and the at least one fan is configured to dissipate heat from the projection module.

4. The electronic apparatus according to claim 3, wherein the projection module comprises a projection unit and a heat dissipating structure, and the heat dissipating structure is connected to the projection unit.

5. The electronic apparatus according to claim 1, further comprising a loudspeaker disposed at the main body, wherein the control module is configured to control the loudspeaker to execute the voice command.

6. The electronic apparatus according to claim 1, wherein the audio receiving module comprises at least one audio receiving unit, a fixing device, and a sound buffer device, the fixing device is disposed at the main body, the at least one audio receiving unit is fixed to the fixing device, and the sound buffer device is connected to the fixing device.

7. The electronic apparatus according to claim 6, wherein the fixing device has opposite outer surface and inner surface, the outer surface faces the outside of the main body, the inner surface faces the inside of the main body, the at least one audio receiving unit is disposed on the outer surface, and the sound buffer device is disposed on the inner surface.

8. The electronic apparatus according to claim 6, wherein the sound buffer device surrounds a plurality of side surfaces of the at least one audio receiving unit.

9. A control method of an electronic apparatus, the electronic apparatus comprising at least one fan, an audio receiving module, and a control module, the control method comprising:
if the audio receiving module receives an activation command, recording an instant value of a rotation speed of the at least one fan and controlling the rotation speed of the at least one fan to be decreased by the control module;
after the rotation speed of the at least one fan is reduced, if the audio receiving module receives a voice command within a predetermined time period, executing the voice command by the electronic apparatus and controlling the rotation speed of the at least one fan to be returned to the instant value of the rotation speed by the control module; and
after the rotation speed of the at least one fan is reduced, if the audio receiving module does not receive the voice command within the predetermined time period, controlling the rotation speed of the at least one fan to be returned to the instant value of the rotation speed by the control module.
